(19) United States
(12) Patent Application Publication
(10) Pub. No.: US 2026/0047255 A1
(43) Pub. Date: Feb. 12, 2026

(54) DISPLAY DEVICE

(71) Applicant: LG Display Co., Ltd., Seoul (KR)

(72) Inventor: SangHoon LEE, Seoul (KR)

(73) Assignee: LG Display Co., Ltd., Seoul (KR)

(21) Appl. No.: 19/247,479

(22) Filed: Jun. 24, 2025

(30) Foreign Application Priority Data
Aug. 9, 2024 (KR) 10-2024-0106841

(51) Int. Cl. H10H 29/41; H10H 29/39

(52) U.S. Cl. CPC H10H 29/41; H10H 29/39

(57) ABSTRACT

A display device can include a substrate which defines a plurality of sub pixels and has a flat portion and a curved portion, a plurality of first assembly electrodes disposed in each of the plurality of sub pixels, a plurality of second assembly electrodes disposed in each of the plurality of sub pixels and spaced apart from the plurality of first assembly electrodes, a first insulating layer disposed on the plurality of first assembly electrodes and the plurality of second assembly electrodes and having a plurality of pocket overlapping the plurality of sub pixels, and a plurality of light emitting diodes disposed in the pockets. A width of a pocket located in the curved portion is different from a width of another pocket located in the flat portion.

### CROSS-REFERENCE TO RELATED APPLICATIONS

This application claims priority to Korean Patent Application No. 10-2024-0106841 filed on Aug. 9, 2024, in the Republic of Korea, the entire disclosure of which is incorporated by reference.

### BACKGROUND

### Field

The present disclosure relates to a display device, and more particularly, to a display device using a light emitting diode (LED).

### Description of the Related Art

Among display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, in recent years, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device which includes an inorganic light emitting diode with excellent luminous efficiency to be driven at a low power.

Another object to be achieved by the present disclosure is to provide a display device in which a light emission direction of a light emitting diode is implemented to be the same in a flat portion and a curved portion.

Still another object to be achieved by the present disclosure is to provide a display device which has an improved front luminance uniformity of a display device including a flat portion and a curved portion.

Objects of the present disclosure are not limited to the above-mentioned objects, and other objects, which are not mentioned above, can be clearly understood by those skilled in the art from the following descriptions.

According to an aspect of the present disclosure, a display device includes a substrate which defines a plurality of sub pixels and has a flat portion and a curved portion, a plurality of first assembly electrodes disposed in each of the plurality of sub pixels, a plurality of second assembly electrodes which is disposed in each of the plurality of sub pixels and is spaced apart from the plurality of first assembly electrodes, a first insulating layer which is disposed on the plurality of first assembly electrodes and the plurality of second assembly electrodes and includes a plurality of pocket overlapping the plurality of sub pixels, and a plurality of light emitting diodes disposed in the pockets of the first insulating layer. A width of a pocket located in the curved portion, among the plurality of pockets, is different from a width of another pocket located in the flat portion. Accordingly, the width of the pocket in the curved portion is formed to be narrow to configure the emission direction of light from each of the light emitting diode disposed in the pocket of the curved portion and the light emitting diode disposed in the pocket of the flat portion to be the same. Further, the front luminance uniformity of the display device can be improved.

Other detailed matters of the example embodiments of the present disclosure are included in the detailed description and the drawings.

According to aspects of the present disclosure, an inorganic light emitting diode with excellent luminous efficiency is included to drive the display device at a low power.

According to aspects of the present disclosure, light emission directions of the light emitting diode are configured to be the same in the flat portion and the curved portion to implement the same level of front luminance.

According to aspects of the present disclosure, the front luminance between the curved portion and the flat portion is implemented to be the same to improve the front luminance uniformity.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an example embodiment of the present disclosure;

FIG. 2 is a schematic partial cross-sectional view of a display device according to an example embodiment of the present disclosure;

FIG. 3 is an enlarged plan view of a display device according to an example embodiment of the present disclosure;

FIG. 4 is an enlarged cross-sectional view of a flat portion of a display device according to an example embodiment of the present disclosure;

FIG. 5 is an enlarged cross-sectional view of a curved portion of a display device according to an example embodiment of the present disclosure;

FIG. 6 is an enlarged cross-sectional view of a flat portion and a curved portion of a display device according to an example embodiment of the present disclosure;

FIG. 7 is a plan view for explaining a method of determining a tilting direction of a light emitting diode of a display device according to an example embodiment of the present disclosure;

FIG. 8 is an enlarged plan view of a display device according to another example embodiment of the present disclosure;

FIG. 9 is an enlarged cross-sectional view of a curved portion of a display device according to another example embodiment of the present disclosure;

FIG. 10 is an enlarged cross-sectional view of a flat portion of a display device according to an example embodiment of the present disclosure; and

FIG. 11 is an enlarged cross-sectional view of a curved portion of a display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately”or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure. Further, the term “can” fully encompasses all the meanings and coverages of the term “may”and vice versa.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to accompanying drawings. All the components of each display device according to all embodiments of the present disclosure are operatively coupled and configured.

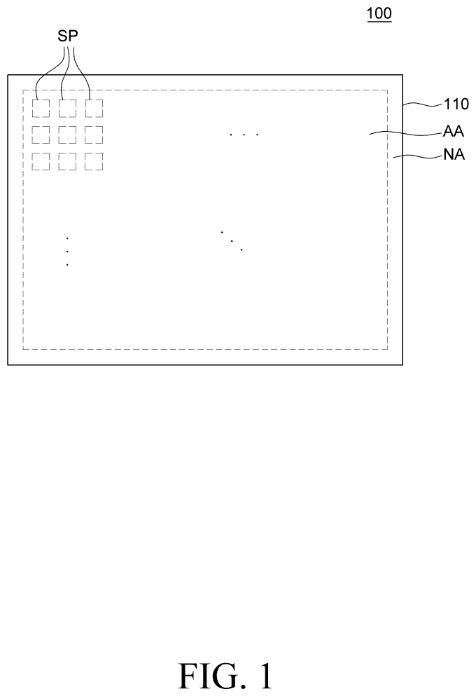

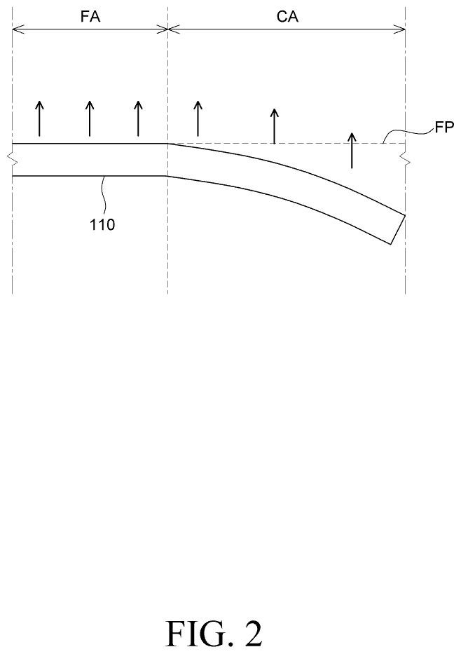

FIG. 1 is a schematic plan view of a display device according to an example embodiment of the present disclosure. FIG. 2 is a schematic partial cross-sectional view of a display device according to an example embodiment of the present disclosure. In FIGS. 1 and 2, for the convenience of description, among various configurations of the display device 100, a substrate 110 is illustrated.

Referring to FIG. 1, the substrate 110 is a component for supporting various components included in the display device 100 and can be formed of an insulating material. For example, the substrate 110 can be formed of glass or resin. Further, the substrate 110 can be formed of polymer or plastic and in some example embodiments, the substrate 110 can be formed of a plastic material having flexibility. A plurality of sub pixels SP is formed on the substrate 110 to display images.

In the substrate 110, an active area AA and a non-active area NA can be defined.

The active area AA is an area in which images are displayed in the display device 100. A plurality of sub pixels SP can be disposed in the active area AA. The plurality of sub pixels SP is minimum units which configure the active area AA and includes a plurality of light emitting diodes to emit light. The plurality of sub pixels SP can display various color light, such as red light, green light, and blue light and display images with various colors with the combination thereof. The plurality of light emitting diodes can be defined in different manners depending on the type of the display device 100. For example, when the display device 100 is an inorganic light emitting display device 100, the light emitting diode can be a light emitting diode (LED) or a micro light emitting diode (micro LED).

In the active area AA, a plurality of signal lines which transmits various signals to the plurality of sub pixels SP is disposed. For example, the plurality of signal lines can include a plurality of power lines which supplies a power voltage to each of the plurality of sub pixels SP.

The non-active area NA is an area where images are not displayed so that the non-active area NA can be defined as an area extending from the active area AA. In the non-active area NA, a link line for transmitting a signal to a sub pixel SP of the active area AA and a pad electrode or a driving IC can be disposed. In the meantime, the non-active area NA can be located on a rear surface of the display device 100, for example, a surface on which the sub pixels SP are not disposed or can be omitted, and is not limited as illustrated in the drawing.

Referring to FIG. 2, the display device 100 can include a flat portion FA and a curved portion CA. The display device 100 can include a curved portion CA formed by at least a portion which is curved. As illustrated in FIG. 2, in the flat portion FA, a surface of the display device 100 can be formed to be flat and in the curved portion CA, a surface of the display device 100 can be formed as a curved surface. For example, when the surface of the display device 100 is located on a virtual plane FP, the flat portion FA of the display device 100 can be disposed so as to correspond to the virtual plane FP. In contrast, the curved portion CA of the display device 100 can be disposed to be inclined with respect to the virtual plane FP at a predetermined angle. The virtual plane FP is a virtual plane FP extending from the flat portion FA and the virtual plane FP and the curved portion CA can be disposed on different planes.

The curved portion CA can be disposed in at least a part of the edge of the display device 100. For example, at least any one of four corners of the display device 100 is bent to form one or more curved portions CA. Further, even when the display device 100 is formed in various shapes such as a circular shape, other than a square shape, a part of the display device 100 is bent to form the curved portion CA.

In the meantime, light from the plurality of light emitting diodes disposed in the display device 100 can travel toward a direction perpendicular to the substrate 110. For example, light from the plurality of light emitting diodes disposed in the flat portion FA can travel in a direction perpendicular to one surface of the substrate 110, for example, a direction perpendicular to the virtual plane FP. For example, light from the light emitting diode disposed in the flat portion FA can travel in a direction as illustrated with an arrow in FIG. 2.

However, the substrate 110 of the display device 100 disposed in the curved portion CA is disposed obliquely to the virtual plane FP and light from the light emitting diode disposed in the curved portion CA can travel in a direction oblique to the virtual plane FP. For example, light from the plurality of light emitting diodes disposed in the curved portion CA does not travel in a direction perpendicular to the virtual plane FP so that the luminance in the front surface of the display device 100 can be degraded. Accordingly, in the display device 100 according to the example embodiment of the present disclosure, the plurality of light emitting diodes disposed in the curved portion CA can be disposed to be oblique in an opposite direction to an angle formed by the curved portion CA and the virtual plane FP. Therefore, light from the plurality of light emitting diodes of the curved portion CA can travel in a direction perpendicular to the virtual plane FP. Therefore, in the display device 100 according to the example embodiment of the present disclosure, the placement angle of the plurality of light emitting diodes of the curved portion CA is controlled to make a traveling direction of light in both the flat portion FA and the curved portion CA an arrow direction of FIG. 2. Further, the luminance in the front surface of the display device 100 can be uniformly maintained.

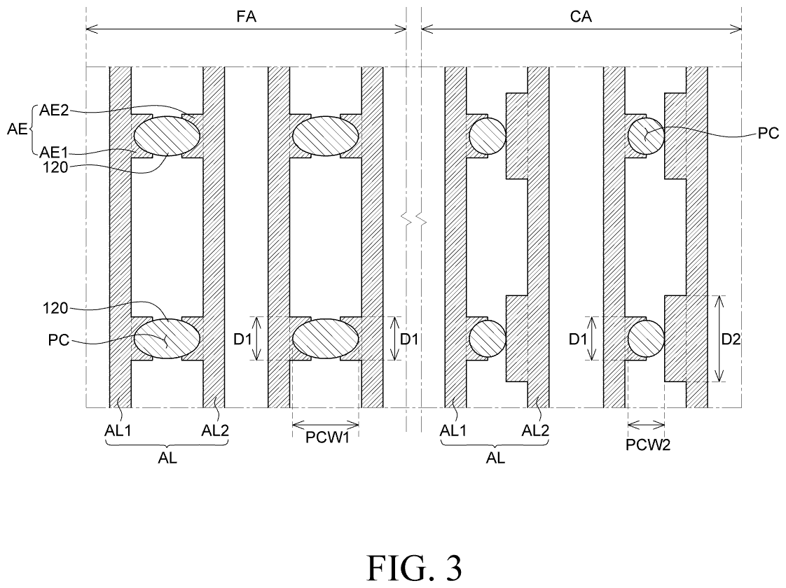

Hereinafter, a placement structure of a plurality of light emitting diodes in each of the flat portion FA and the curved portion CA will be described in detail with reference to FIGS. 3 to 7.

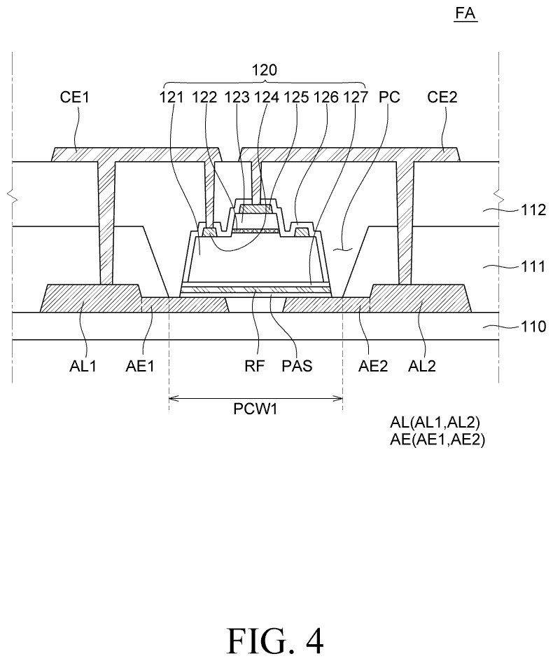

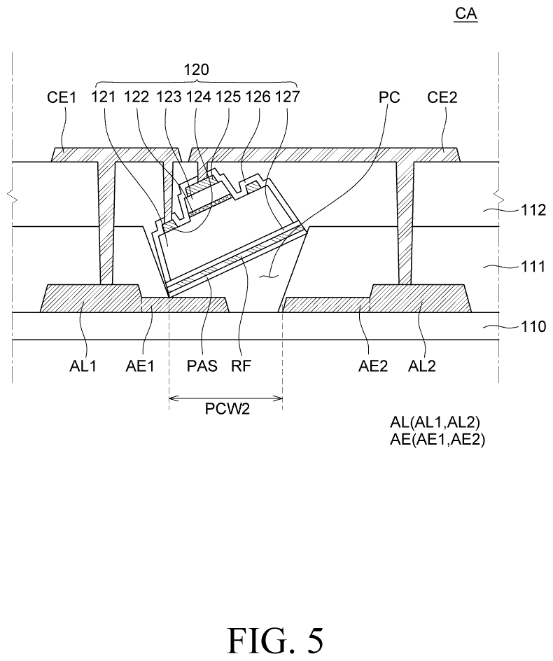

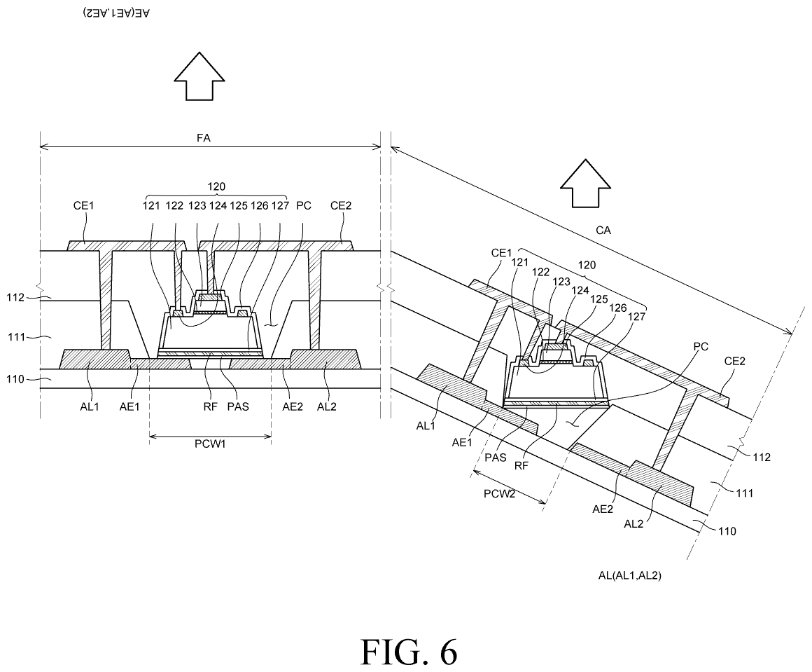

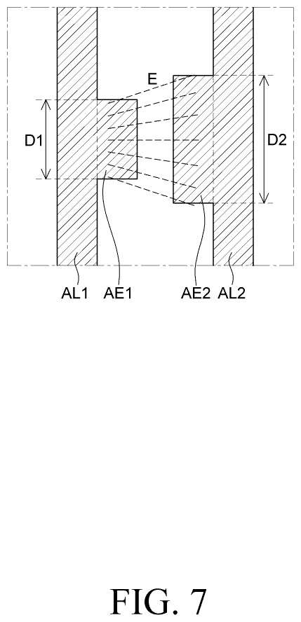

FIG. 3 is an enlarged plan view of a display device according to an example embodiment of the present disclosure. FIG. 4 is an enlarged cross-sectional view of a flat portion of a display device according to an example embodiment of the present disclosure. FIG. 5 is an enlarged cross-sectional view of a curved portion of a display device according to an example embodiment of the present disclosure. FIG. 6 is an enlarged cross-sectional view of a flat portion and a curved portion of a display device according to an example embodiment of the present disclosure. FIG. 7 is a plan view for explaining a method of determining a tilting direction of a light emitting diode of a display device according to an example embodiment of the present disclosure.

Referring to FIGS. 3 to 5, the display device 100 includes a substrate 110, a first insulating layer 111, a second insulating layer 112, a plurality of light emitting diodes 120, a plurality of assembly lines AL, a plurality of assembly electrodes AE, a first connection electrode CE1, and a second connection electrode CE2.

First, a plurality of assembly lines AL is disposed on the substrate 110. The plurality of assembly lines AL is wiring lines which generate an electric field to self-assemble the plurality of light emitting diodes 120 while manufacturing the display device 100 and supply a driving voltage to the plurality of light emitting diodes 120 while driving the display device 100. The plurality of assembly lines AL can be disposed along the plurality of sub pixels SP disposed on the same line. The plurality of assembly lines AL can be disposed so as to overlap the plurality of sub pixels SP disposed on the same column. For example, a first assembly line AL1 and a second assembly line AL2 can be disposed along the plurality of sub pixels SP disposed in the same column.

The plurality of assembly lines AL includes a plurality of first assembly lines AL1 and a plurality of second assembly lines AL2. The plurality of first assembly lines AL1 and the plurality of second assembly lines AL2 can be alternately disposed. The plurality of first assembly lines AL1 and the plurality of second assembly lines AL2 can be disposed to be spaced apart from each other with a predetermined interval. In each of the plurality of sub pixels SP, one first assembly line AL1 and one second assembly line AL2 can be disposed to be adjacent to each other. When the display device 100 is driven, different driving voltages are applied to the plurality of first assembly lines AL1 and the plurality of second assembly lines AL2 to drive the plurality of light emitting diodes 120 in a passive matrix (PM) manner.

If the plurality of light emitting diodes 120 is driven in the passive matrix manner, the display device 100 can be used for an illumination device. For example, all or some of the plurality of light emitting diodes 120 are on or off to use the display device as an illumination device which is capable of displaying various colors and luminous intensities. However, the display device 100 can further include a driving element, such as a driving transistor to be driven in an active matrix (AM) manner, without being limited thereto.

The plurality of assembly electrodes AE is disposed in each of the plurality of sub pixels SP on the substrate 110. The plurality of assembly electrodes AE includes a plurality of first assembly electrodes AE1 and a plurality of second assembly electrodes AE2. The plurality of first assembly electrodes AE1 can be connected to the plurality of first assembly lines AL1 and the plurality of second assembly electrodes AE2 can be connected to the plurality of second assembly lines AL2. One pair of first assembly electrode AE1 and second assembly electrode AE2 is disposed to be adjacent to each other to form an electric field to self-assemble the light emitting diode 120. One pair of first assembly electrode AE1 and second assembly electrode AE2 can be disposed so as to overlap a position in which the light emitting diode 120 is disposed in the plurality of sub pixels SP.

A voltage is applied to the plurality of assembly lines AL and the plurality of assembly electrodes AE to self-assemble the plurality of light emitting diodes 120 in a pocket PC of each of the plurality of sub pixels SP. For example, AC voltages are applied to the plurality of first assembly lines AL1 and the plurality of first assembly electrodes AE1 and the plurality of second assembly lines AL2 and the plurality of second assembly electrodes AE2 to form an electric field. The light emitting diode 120 is dielectrically polarized by the electric field to have a polarity. The dielectrically polarized light emitting diode 120 can move or can be fixed to a specific direction by dielectrophoresis (DEP), for example, an electric field. Accordingly, the plurality of light emitting diodes 120 can be self-assembled in the pocket PC of the plurality of sub pixels SP using dielectrophoresis.

The plurality of assembly lines AL and the plurality of assembly electrodes AE can be formed of a conductive material, such as copper (Cu), chrome (Cr), or molybdenum (Mo), molybdenum titanium (MoTi), but are not limited thereto. Further, the plurality of assembly lines AL and the plurality of assembly electrodes AE can be formed by a plurality of conductive layers. For example, the plurality of assembly lines AL and the plurality of assembly electrodes AE can be formed with a double layered structure of a conductive layer having a more excellent conductivity and a clad layer which is disposed so as to cover the conductive layer and is relatively robust to corrosion, but are not limited thereto.

A thickness of the plurality of assembly lines AL can be larger than a thickness of the plurality of assembly electrodes AE. For example, the thickness of the plurality of assembly lines AL is formed to be larger to lower the line resistance and the voltage can be more easily applied from the plurality of assembly lines AL to the plurality of assembly electrodes AE. However, the thickness of the plurality of assembly lines AL can be formed to be the same as the thickness of the plurality of assembly electrodes AE, but is not limited thereto.

A first insulating layer 111 is disposed on the plurality of assembly lines AL and the plurality of assembly electrodes AE. The first insulating layer 111 can be disposed so as to cover a front surface of the substrate 110 on which the plurality of assembly lines AL and the plurality of assembly electrodes AE are formed. The first insulating layer 111 can be configured by a single layer or a double layer of an organic insulating material, and for example, configured by benzocyclobutene or an acrylic organic material, but is not limited thereto.

The first insulating layer 111 can include a plurality of pockets PC. The plurality of pockets PC is openings in which the plurality of light emitting diodes 120 is self-assembled. Each of the plurality of pockets PC can be formed in a position corresponding to each of the plurality of sub pixels SP. The plurality of pockets PC can be disposed so as to overlap an area between one pair of the first assembly electrode AE1 and the second assembly electrode AE2. Each of the plurality of pockets PC can be formed so as to correspond each of the plurality of sub pixels SP one to one. In each of the plurality of pockets PC, at least any one of the first assembly electrode AE1 and the second assembly electrode AE2 can be exposed. For example, in the flat portion FA, both the first assembly electrode AE1 and the second assembly electrode AE2 can overlap the pocket PC. For example, in the curved portion CA, only any one of the first assembly electrode AE1 and the second assembly electrode AE2 overlaps the pocket PC or an area of the first assembly electrode AE1 overlapping the pocket PC and an area of the second assembly electrode AE2 overlapping the pocket PC can be different from each other. A width of the plurality of pockets PC can vary depending on an angle between the substrate 110 and the virtual plane FP, which will be described in more detail below.

Next, the light emitting diode 120 is disposed in each of the plurality of pockets PC. The light emitting diode 120 includes a first semiconductor layer 121, an emission layer 122, a second semiconductor layer 123, a first electrode 124, a second electrode 125, a first encapsulation film 126, and a second encapsulation film 127.

First, the first semiconductor layer 121 is disposed on the plurality of assembly electrodes AE and the second semiconductor layer 123 is disposed on the first semiconductor layer 121. The first semiconductor layer 121 and the second semiconductor layer 123 can be semiconductor layers doped with n-type and p-type impurities. For example, the first semiconductor layer 121 and the second semiconductor layer 123 can be semiconductor layers doped with n-type or p-type impurities into a material such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium, and tin (Sn), but they are not limited thereto.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 can be formed by a single layer or a multi-quantum well (MQW) structure, and for example, can be formed of indium gallium nitride (InGaN) or gallium nitride (GaN), but is not limited thereto.

The first electrode 124 is disposed on the first semiconductor layer 121. The first electrode 124 is an electrode which electrically connects the first connection electrode CE1 and the first semiconductor layer 121. The first electrode 124 can be disposed on a top surface of the first semiconductor layer 121 which is exposed from the emission layer 122 and the second semiconductor layer 123. One or more first electrodes 124 can be disposed on the top surface of the first semiconductor layer 121. For example, a planar shape of the first semiconductor layer 121 can be an oval shape and in a major axis direction, the first electrodes 124 can be disposed on both end portions of the top surface of the first semiconductor layer 121. For example, one pair of first electrodes 124 can be disposed on the top surface of the first semiconductor layer 121 with the emission layer 122 and the second semiconductor layer 123 therebetween. The first electrode 124 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 can be disposed on the top surface of the second semiconductor layer 123. The second electrode 125 is an electrode which electrically connects a second connection electrode CE2 and the second semiconductor layer 123. The second electrode 125 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the first encapsulation film 126 which encloses the first semiconductor layer 121, the emission layer 122, the second semiconductor layer 123, the first electrode 124, and the second electrode 125 is disposed. The first encapsulation film 126 is formed of an insulating material to protect the first semiconductor layer 121, the emission layer 122, and the second semiconductor layer 123. The first encapsulation film 126 can be formed so as to cover a side surface and a top surface of the first semiconductor layer 121, a side surface of the emission layer 122, a side surface and a top surface of the second semiconductor layer 123, the first electrode 124, and the second electrode 125. In the first encapsulation film 126, a contact hole which exposes the first electrode 124 and the second electrode 125 is formed to electrically connect the first connection electrode CE1 and the second connection electrode CE2 to the first electrode 124 and the second electrode 125.

The second encapsulation film 127 can be disposed between the first semiconductor layer 121 and a reflective film RF. The second encapsulation film 127 is formed of an insulating material to protect the first semiconductor layer 121. The second encapsulation film 127 can be disposed so as to cover the entire bottom surface of the first semiconductor layer 121. The second encapsulation film 127 is disposed so as to enclose the first semiconductor layer 121 together with the first encapsulation film 126 to protect the first semiconductor layer 121. As described above, the second encapsulation film 127 can be disposed so as to protect the first semiconductor layer 121, but is not limited thereto so that the first semiconductor layer 121 can be in direct contact with the reflective film RF without the second encapsulation film 127.

The first encapsulation film 126 and the second encapsulation film 127 can be formed of a transparent insulating material, and for example, can be configured by a single layer or a double layer of silicon oxide (SiOx) or silicon nitride (SiNx), but are not limited thereto.

When the light emitting diode 120 is formed, semiconductor materials which form the first semiconductor layer 121, the emission layer 122, and the second semiconductor layer 123 are sequentially grown on the wafer and then are patterned into a plurality of pieces. The first electrode 124, the second electrode 125, and the first encapsulation film 126 which covers the first and second electrodes are formed. By doing this, the plurality of light emitting diodes 120 can be formed. Finally, the plurality of light emitting diodes 120 is separated from the wafer to expose the bottom surface of the first semiconductor layer 121 and then the second encapsulation film 127 can be formed. However, the first encapsulation film 126 and the second encapsulation film 127 can be formed by various method other than this, but are not limited thereto.

Next, the reflective film RF is disposed below the light emitting diode 120. The reflective film RF can be disposed between the second encapsulation film 127 and the first assembly electrode AE1 and the second assembly electrode AE2. The reflective film RF can reflect light emitted from the light emitting diode 120 toward the top of the substrate 110. Therefore, the display device 100 in which the reflective film RF is formed below the light emitting diode 120 can be a top emission type in which the light emitted from the light emitting diode 120 travels toward an upper direction of the substrate 110. The reflective film RF is formed of a conductive material having excellent reflecting property to reflect light emitted from the light emitting diode 120 toward the upper portion of the light emitting diode 120. The reflective film RF can be formed together when the second encapsulation film 127 is formed, but is not limited thereto and can be formed below the light emitting diode 120 so as to overlap the light emitting diode 120, separately from the light emitting diode 120. When the reflective film RF and the light emitting diode 120 are separately formed, the reflective film RF can be formed below the first assembly electrode AE1 and the second assembly electrode AE2. In this case, an insulating layer, such as a passivation layer PAS, can be further disposed between the reflective film RF and the plurality of assembly electrodes AE and between the reflective film RF and the plurality of assembly lines AL. Therefore, a short-circuit defect that one pair of assembly electrodes AE is connected to each other by the reflective film RF can be suppressed. The reflective film RF can be formed of a material, such as silver (Ag), aluminum (Al), molybdenum (Mo), titanium (Ti), or an alloy thereof, but is not limited thereto.

Next, the passivation layer PAS is disposed between the reflective film RF and the assembly electrode AE. The passivation layer PAS can be disposed so as to cover the reflective film RF. The passivation layer PAS can separate the assembly electrodes AE and the reflective film RF so as not to allow the pair of assembly electrodes AE to be connected to each other by the reflective film RF. The passivation layer PAS can be formed when the reflective film RF is formed. The passivation layer PAS can be formed of an insulating material, for example, can be configured by a single layer or a double layer of silicon oxide (SiOx) and silicon nitride (SiNx), but is not limited thereto.

Even though in the drawing, it is illustrated that the passivation layer PAS covers the reflective film RF, the passivation layer PAS can be disposed so as to cover the plurality of assembly lines AL and the plurality of assembly electrodes AE, instead of the reflective film RF, but is not limited thereto.

The second insulating layer 112 is disposed on the light emitting diode 120 and the first insulating layer 111. The second insulating layer 112 can be disposed so as to cover the first insulating layer 111 and the light emitting diode 120. The second insulating layer 112 is disposed so as to cover the light emitting diode 120 to fix and protect the light emitting diode 120. The second insulating layer 112 can be configured by a single layer or a double layer of an organic insulating material, and for example, configured by benzocyclobutene or an acrylic organic material, but is not limited thereto.

The first connection electrode CE1 is disposed in each of the plurality of sub pixels SP on the second insulating layer 112. The first connection electrode CE1 is an electrode for electrically connecting the light emitting diode 120 and the first assembly line AL1. The first connection electrode CE1 can be connected to any one of the plurality of first electrodes 124 of the light emitting diode 120 through a contact hole formed in the second insulating layer 112. The first connection electrode CE1 can be connected to the first assembly line AL1 through the contact holes formed in the second insulating layer 112 and the first insulating layer 111. Accordingly, the first electrode 124 and the first semiconductor layer 121 of the light emitting diode 120 can be electrically connected to the first assembly electrode AL1 by means of the first connection electrode CE1.

The second connection electrode CE2 can be disposed in each of the plurality of sub pixels SP on the second insulating layer 112 to be spaced apart from the first connection electrode CE1. The second connection electrode CE2 is an electrode for electrically connecting the light emitting diode 120 and the second assembly line AL2. The second connection electrode CE2 can be electrically connected to the second electrode 125 of the light emitting diode 120 through a contact hole formed in the second insulating layer 112. The second connection electrode CE2 can be connected to the second assembly line AL2 through the contact holes formed in the second insulating layer 112 and the first insulating layer 111. Accordingly, the second electrode 125 and the second semiconductor layer 123 of the light emitting diode 120 can be electrically connected to the second assembly electrode AL2 by means of the second connection electrode CE2.

The first connection electrode CE1 and the second connection electrode CE2 can be formed of a transparent conductive material to allow light emitted from the light emitting diode 120 to be directed to the upper portion of the substrate 110. For example, the first connection electrode CE1 and the second electrode CE2 can be formed of a transparent conductive material, such as indium tin oxide (ITO) or indium zinc oxide (IZO), but are not limited thereto.

Referring to FIGS. 4 and 6, the plurality of pockets PC disposed in the flat portion FA can be disposed in an area between the first assembly electrode AE1 and the second assembly electrode AE2. A center of the pocket PC can correspond to a center area between the first assembly electrode AE1 and the second assembly electrode AE2. In the flat portion FA, an overlapping area of the first assembly electrode AE1 and the pocket PC can be equal to an overlapping area of the second assembly electrode AE2 and the pocket PC. In the flat portion FA, the plurality of pockets PC can be disposed with a symmetrical structure without being biased to any one of the first assembly electrode AE1 and the second assembly electrode AE2.

The plurality of pockets PC disposed in the flat portion FA can have a first width PCW1. In this case, a first width PCW1 of the pocket PC can be the minimum width of the pocket PC. For example, the first width PCW1 of the pocket PC can be the width of the pocket PC at a surface where the first assembly electrode AE1 and the second assembly electrode AE2 are exposed. The first width PCW1 can be a value larger than the maximum width of the light emitting diode 120. The pocket PC of the flat portion FA has the first width PCW1 which is larger than the maximum width of the light emitting diode 120 to allow the light emitting diode 120 to be seated in the pocket PC. The pocket PC of the flat portion FA has a size larger than the light emitting diode 120 so that the light emitting diode 120 which is self-assembled in the pocket PC of the flat portion FA can be disposed on the first assembly electrode AE1 and the second assembly electrode AE2 without being interfered with the pocket PC. The light emitting diode 120 disposed in the pocket PC of the flat portion FA can be disposed such that one surface of the light emitting diode 120 is parallel to one surface of the substrate 110 and the virtual plane FP.

Referring to FIGS. 5 and 6, the plurality of pockets PC disposed in the curved portion CA can be disposed to be biased to any one of the first assembly electrode AE1 and the second assembly electrode AE2. For example, when the light emitting diode 120 is tilted toward the first assembly electrode AE1, the pocket PC is disposed to be biased to the first assembly electrode AE1 so that the first assembly electrode AE1 can be exposed from the pocket PC and at least a part of the second assembly electrode AE2 can be disposed below the first insulating layer 111. An area of the first assembly electrode AE1 which is exposed from the first insulating layer 111 can be larger than an area of the second assembly electrode AE2 which is exposed from the first insulating layer 111.

The plurality of pockets PC disposed in the curved portion CA can have a width smaller than the first width PCW1. For example, any one of the plurality of pockets PC of the curved portion CA can have a second width PCW2 which is smaller than the first width PCW1. Here, as in the case of the first width PCW1, the second width PCW2 can also represent a minimum width of any one of the plurality of pockets PC located in the curved portion CA. For example, the second width PCW2 of the pocket PC of the curved portion CA can be the width of the pocket PC at a surface where the first assembly electrode AE1 and the second assembly electrode AE2 are exposed. The second width PCW2 can be a value smaller than the maximum width of the light emitting diode 120. The pocket PC of the curved portion CA has the second width PCW2 which is smaller than the maximum width of the light emitting diode 120 to place the light emitting diode 120 obliquely in the pocket PC. The pocket PC of the curved portion CA has a size smaller than the light emitting diode 120 so that the pocket PC of the curved portion CA and the light emitting diode 120 can interfere with each other. Accordingly, the light emitting diode 120 disposed in the pocket PC of the curved portion CA is disposed obliquely to one surface of the substrate 110 so that one surface of the emission layer 122 can be disposed obliquely to one surface of the substrate 110. Therefore, one surface of the emission layer 122 of the light emitting diode 120 disposed in the pocket PC of the curved portion CA is disposed obliquely to one surface of the substrate 110, but can be disposed to be parallel to the virtual plane FP, like one surface of the emission layer 122 of the light emitting diode 120 disposed in the flat portion FA.

The larger the angle between the substrate 110 and the virtual plane FP, the smaller the width of the pocket PC of the curved portion CA. For example, when the farther from the flat portion FA, the larger the angle between the curved portion CA and the virtual plane FP, the farther from the flat portion FA, the smaller the width of the pocket PC of the curved portion CA. For example, when in a partial area of the curved portion CA, an angle between the substrate 110 and the virtual plane FP is 10 degrees and in the other partial area of the curved portion CA, an angle between the substrate 110 and the virtual plane FP is 30 degrees, the light emitting diode 120 is disposed to have a gentler slope in an area in which the angle is 10 degrees rather than in an area in which the angle is 30 degrees. By doing this, the virtual plane FP and the emission layer 122 can be disposed to be parallel. In contrast, in the area in which the angle is 30 degrees, the light emitting diode 120 is disposed to have a relatively steep slope to place the virtual plane FP and the emission layer 122 to be parallel. At this time, in the curved portion CA, the emission layer 122 in an area in which the angle is 20 degrees, the emission layer 122 in an area in which the angle is 10 degrees, and the emission layer 122 disposed in the flat portion FA can be disposed to be parallel.

As the width of the pocket PC is increased, the light emitting diode 120 can be disposed with a gentle slope and as the width of the pocket PC is decreased, the light emitting diode 120 can be disposed with a steep slope. The larger the width of the pocket PC, the smaller the slope of the light emitting diode 120 and the smaller the width of the pocket PC, the larger the slope of the light emitting diode 120.

Referring to FIGS. 3 and 7 together, a tilting direction of the light emitting diode 120 can be controlled by varying the sizes of the first assembly electrode AE1 and the second assembly electrode AE2. The tilting direction of the light emitting diode 120 can be determined in accordance with the lengths of the first assembly electrode AE1 and the second assembly electrode AE2 on the plane. For example, the first assembly electrode AE1 and the second assembly electrode AE2 in the flat portion FA can have the same length and the first assembly electrode AE1 and the second assembly electrode AE2 in the curved portion CA can have different lengths. For example, on the plane, the first assembly electrode AE1 can have a first length D1 and the second assembly electrode AE2 can have a second length D2 which is longer than the first length D1. When the light emitting diode 120 is self-assembled, an electric field E formed between the first assembly electrode AE1 and the second assembly electrode AE2 can be irregular. For example, in the first assembly electrode AE1 which is shorter and smaller, the electric field E can be formed at a high density and in the second assembly electrode AE2 which is longer and larger, the electric field E can be formed at a low density. When the light emitting diode 120 is self-assembled, the light emitting diode 120 can priorly move toward an area where the electric field E is formed at a high density rather than an area where the electric field E is formed at a low density. A tilting direction of the light emitting diode 120 can be determined to be in contact with the assembly electrode AE in which the high density electric field E is formed priorly. For example, the light emitting diode 120 has a relatively small size to be aligned to be directed to the first assembly electrode AE1 in which a high density electric field E is formed and moves toward the pocket PC.

For example, a size of the first assembly electrode AE1, between the first assembly electrode AE1 and the second assembly electrode AE2, is formed to be small to tilt the light emitting diode 120 to be directed to the first assembly electrode AE1. For example, a size of the second assembly electrode AE2, between the first assembly electrode AE1 and the second assembly electrode AE2, is formed to be small to tilt the light emitting diode 120 to be directed to the second assembly electrode AE2. Accordingly, between one pair of assembly electrodes AE, an assembly electrode AE located in a direction to which the light emitting diode 120 is to be tilted is formed to be small to determine the tilting direction of the light emitting diode 120.

At this time, in the flat portion FA in which the light emitting diode 120 is disposed in the pocket PC without being tilted, the first assembly electrode AE1 and the second assembly electrode AE2 can have the same size. For example, on the plane, the first assembly electrode AE1 and the second assembly electrode AE2 can be formed to have the same first length L1. Accordingly, a uniform electric field E can be formed between the first assembly electrode AE1 and the second assembly electrode AE2 having the same size and the light emitting diode 120 can be disposed to be parallel to one surface of the substrate 110.

Therefore, in the display device 100 according to the example embodiment of the present disclosure, a width of the plurality of pockets PC disposed in the curved portion CA is adjusted according to an angle between the substrate 110 and the virtual plane FP. By doing this, one surface of the emission layer 122 of the plurality of light emitting diodes 120 disposed in the curved portion CA can be disposed to be parallel to the virtual plane FP. In this case, the emission layers 122 of both the light emitting diode 120 of the flat portion FA and the light emitting diode 120 of the curved portion CA are disposed to be parallel to the virtual plane FP. Further, light emitted from the light emitting diode 120 of the flat portion FA can travel in a direction perpendicular to the virtual plane FP and light emitted from the light emitting diode 120 of the curved portion CA can also travel in a direction perpendicular to the virtual plane FP. The light emitted from the light emitting diode 120 of the flat portion FA and the light emitted from the light emitting diode 120 of the curved portion CA can be emitted to the same direction. Accordingly, the light emitted from the plurality of light emitting diodes can be uniformly emitted in a direction perpendicular to the virtual plane FP without being limited to the angle of the substrate 110 in each of the flat portion FA and the curved portion CA and the luminance uniformity in the front surface of the display device 100 can be improved.

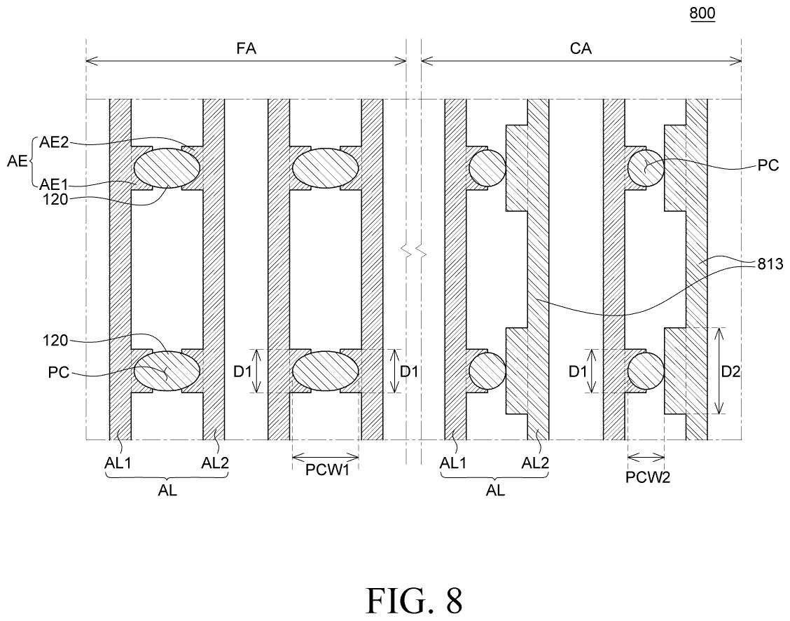

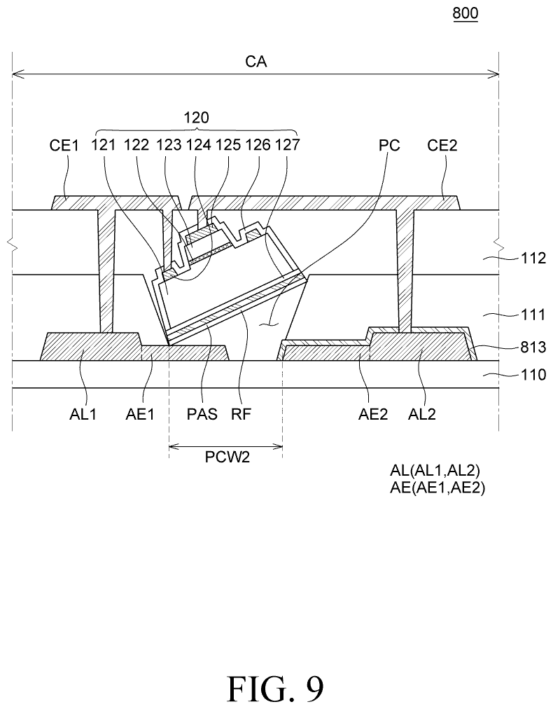

FIG. 8 is an enlarged plan view of a display device according to another example embodiment of the present disclosure. FIG. 9 is an enlarged cross-sectional view of a curved portion of a display device according to another example embodiment of the present disclosure. As compared with the display device 100 of FIGS. 1 to 7, a display device 800 of FIGS. 8 and 9 further includes a third insulating layer 813, but other configurations are substantially the same, so that a redundant description will be omitted or may be briefly provided.

Referring to FIGS. 8 and 9, a third insulating layer 813 which covers a part of the plurality of assembly lines AL and the plurality of assembly electrodes AE of the curved portion CA is formed. The third insulating layer 813 can be disposed between the first insulating layer 111 and some assembly line AL and between the first insulating layer 111 and some assembly electrode AE. The third insulating layer 813 can be disposed on the assembly line AL and the assembly electrode AE located in an opposite direction to the tilting direction of the plurality of light emitting diodes 120. For example, the light emitting diode 120 can be disposed to be tilted toward an assembly electrode AE which is spaced apart from the third insulating layer 813, between the first assembly electrode AE1 and the second assembly electrode AE2. For example, the plurality of light emitting diodes 120 located in the curved portion CA is tilted toward the first assembly electrode AE1 between the first assembly electrode AE1 and the second assembly electrode AE2, the third insulating layer 813 which covers the second assembly electrode AE2 and the second assembly line AL2 can be disposed. The third insulating layer 813 can be configured by a single layer or a double layer of silicon oxide (SiOx) or silicon nitride (SiNx), but is not limited thereto.

The third insulating layer 813 can be formed on only the second assembly electrode AE2 and the second assembly line AL2 to induce the tilting direction of the light emitting diode 120 so as to allow the light emitting diode 120 to be in contact with the first assembly electrode AE1 first. If the third insulating layer 813 is additionally formed only on the second assembly electrode AE2, when the light emitting diode 120 is self-assembled, dielectrophoresis (DEP) force which is applied to the light emitting diode 120 from the second assembly electrode AE2 is weakened to induce the light emitting diode 120 toward the first assembly electrode AE1 priorly. For example, the electric field E from the second assembly electrode AE2 can be weakened while passing through the third insulating layer 813 so that the dielectrophoresis force which induces the light emitting diode 120 to the second assembly electrode AE2 can also be weakened. Accordingly, the third insulating layer 813 is additionally formed only on the second assembly electrode AE2 and the second assembly line AL2 to weaken the dielectrophoresis force by the second assembly electrode AE2 to be weaker than the dielectrophoresis force by the first assembly electrode AE1. Further, the light emitting diode 120 can be induced to be self-assembled to be biased to the first assembly electrode AE1. In contrast, in order to induce to light emitting diode 120 to be tilted to the second assembly electrode AE2, the third insulating layer 813 is additionally formed only on the first assembly electrode AE1 and the first assembly line AL1 to induce the light emitting diode 120 to be in contact with the second assembly electrode AE2 priorly.

Accordingly, in the display device 800 according to another example embodiment of the present disclosure, the third insulating layer 813 is formed on the assembly electrode AE and the assembly line AL disposed in an opposite direction to the tilting direction of the light emitting diode 120. By doing this, the light emitting diode 120 can be tilted toward the assembly electrode AE in which the third light emitting diode 813 is not formed. For example, in order to self-assemble the light emitting diode 120 to be tilted to the first assembly electrode AE1, the third insulating layer 813 is formed only on the second assembly electrode AE2 to tilt the light emitting diode 120 to be in contact with the first assembly electrode AE1 priorly. In contrast, in order to tilt the light emitting diode 120 to the second assembly electrode AE2, the third insulating layer 813 can be formed only on the first assembly electrode AE1. Accordingly, the third insulating layer 813 is formed only on some assembly line AL and assembly electrode AE located in an opposite direction to the tilting direction, among the plurality of assembly lines AL and the plurality of assembly electrodes AE of the curved portion CA. Therefore, the tilting direction of the light emitting diode 120 can be induced to the assembly electrode AE and the assembly line AL in which the third insulating layer 813 is not formed.

In FIG. 8, it is illustrated that in order to tilt the light emitting diode 120 toward the first assembly electrode AE1 as illustrated in FIG. 3, the second length D2 of the second assembly electrode AE2 is longer than the first length D1 of the first assembly electrode AE1, but it is not limited thereto. As described above, the third insulating layer 813 which is formed only on the second assembly electrode AE2 can weaken the dielectrophoresis force of the second assembly electrode AE2. Therefore, unlike FIG. 8, in the curved portion CA, the first length D1 of the first assembly electrode AE1 is formed to be the same as the second length D2 of the second assembly electrode AE2 like in the flat portion FA. Further, as illustrated in FIG. 9, the third insulating layer 813 can be formed only on the second assembly electrode AE2 to tilt the light emitting diode 120 toward the first assembly electrode AE1. In this case, the tilting angle of the light emitting diode 120 is adjusted by adjusting the thickness of the third insulating layer 813.

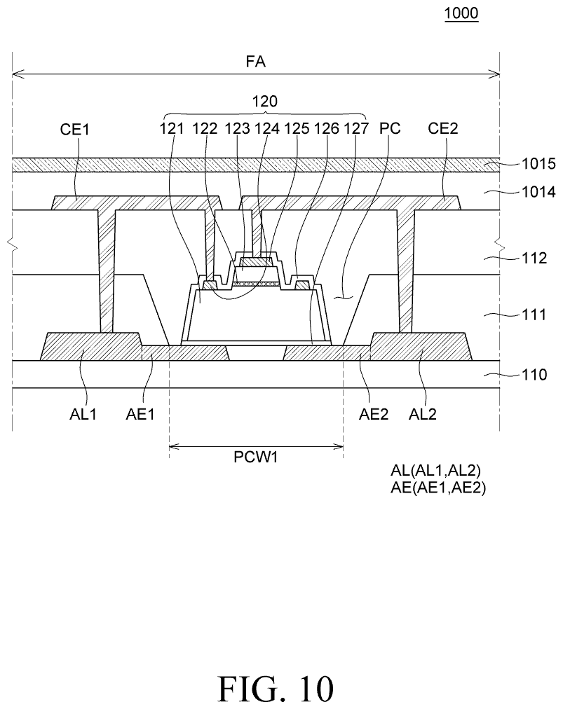

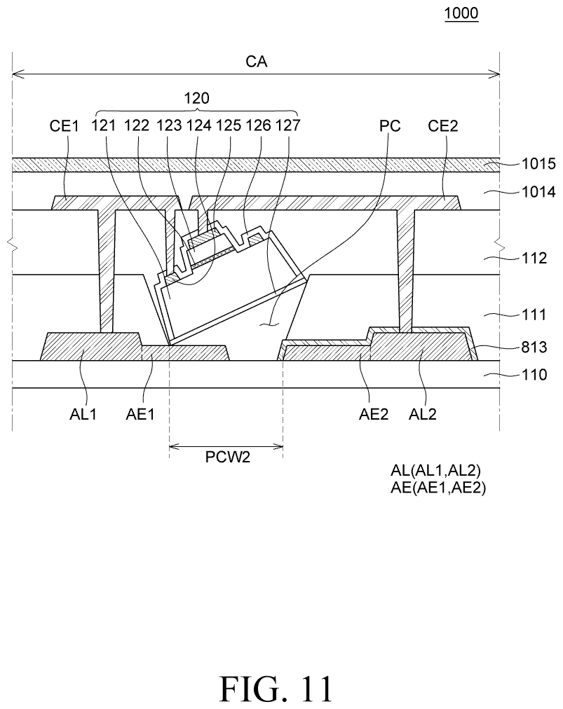

FIG. 10 is an enlarged cross-sectional view of a flat portion of a display device according to an example embodiment of the present disclosure. FIG. 11 is an enlarged cross-sectional view of a curved portion of a display device according to an example embodiment of the present disclosure. As compared with the display device 800 of FIGS. 8 and 9, except that a display device 1000 of FIGS. 10 and 11 does not include a reflective film RF, but further includes a fourth insulating layer 1014 and a reflection layer 1015, other configurations are substantially the same so that a redundant description will be omitted or may be briefly provided.

Referring to FIGS. 10 and 11, a fourth insulating layer 1014 is disposed on the first connection electrode CE1, the second connection electrode CE2, and the second insulating layer 112. The fourth insulating layer 1014 can be entirely disposed in the flat portion FA and the curved portion CA. The fourth insulating layer 1014 can be configured by a single layer or a double layer of an organic insulating material, and for example, configured by benzocyclobutene or an acrylic organic material, but is not limited thereto.

The reflection layer 1015 is disposed on the fourth insulating layer 1014. The reflection layer 1015 can be disposed on the entire substrate 110 on the fourth insulating layer 1014. The reflection layer 1015 can reflect light emitted from the light emitting diode 120 toward the lower portion of the substrate 110. Therefore, the display device 1000 in which the reflection layer 1015 is formed on the light emitting diode 120 can be a bottom emission type in which the light emitted from the light emitting diode 120 travels toward a lower direction of the substrate 110. The reflection layer 1015 is formed of a conductive material having excellent reflecting property to reflect the light emitted from the light emitting diode 120 toward the substrate 110. For example, the reflection layer 1015 can be formed of a material, such as silver (Ag), aluminum (Al), or molybdenum (Mo), titanium (Ti), or an alloy thereof, but is not limited thereto. Accordingly, in the display device 1000 according to another example embodiment of the present disclosure, the reflection layer 1015 is formed on the plurality of light emitting diodes 120 to implement the bottom-emission type display device 1000. In the case of the bottom emission type, in order to increase light emission efficiency, the first connection electrode CE1 and the second connection electrode CE2 can be configured by a material having a high reflectance and the assembly electrodes AE, AE1, and AE2 can be configured by a transparent material.

The example embodiments of the present disclosure can also be described as follows:

According to an aspect of the present disclosure, a display device includes a substrate which defines a plurality of sub pixels and has a flat portion and a curved portion, a plurality of first assembly electrodes disposed in each of the plurality of sub pixels, a plurality of second assembly electrodes which is disposed in each of the plurality of sub pixels and is spaced apart from the plurality of first assembly electrodes, a first insulating layer which is disposed on the plurality of first assembly electrodes and the plurality of second assembly electrodes and includes a plurality of pocket overlapping the plurality of sub pixels, and a plurality of light emitting diodes disposed in the pockets of the first insulating layer. A width of some pocket located in the curved portion, among the plurality of pockets, is different from a width of the other pocket located in the flat portion.

The width of some pocket located in the curved portion can be smaller than the width of the other pocket located in the flat portion.

A slope of some light emitting diode disposed in the curved portion, among the plurality of light emitting diodes, can be different from a slope of the other light emitting diode disposed in the flat portion.

The width of some pocket located in the curved portion can vary according to an angle between a virtual plane extending from the flat portion and one surface of the substrate of the curved portion.

The larger the angle between the virtual plane and one surface of the substrate of the curved portion, the width of some pocket located in the curved portion can become smaller.

The width of some pocket located in the curved portion can be smaller than a maximum width of each of the plurality of light emitting diodes.

Some light emitting diode disposed in the curved portion, among the plurality of light emitting diodes, can be disposed to be tilted toward any one of the first assembly electrode and the second assembly electrode.

A width of the other pocket located in the flat portion can be larger than a maximum width of each of the plurality of light emitting diodes.

The other light emitting diode disposed in the flat portion, among the plurality of light emitting diodes, can be disposed to be parallel to one surface of each of the first assembly electrode and the second assembly electrode.

An emission layer of some light emitting diode disposed in the curved portion, among the plurality of light emitting diodes, can be disposed to be tilted with respect to one surface of the substrate and an emission layer of the other light emitting diode disposed in the flat portion, among the plurality of light emitting diodes, can be disposed to be parallel to the one surface of the substrate.

The emission layer of some light emitting diode disposed in the curved portion and the emission layer of the other light emitting diode disposed in the flat portion can be disposed to be parallel to each other.

The emission layer of some light emitting diode disposed in the curved portion and the emission layer of the other light emitting diode disposed in the flat portion can be disposed to be parallel to a virtual plane extending from the flat portion.

The plurality of first assembly electrodes and the plurality of second assembly electrodes disposed in the flat portion can have the same size and the plurality of first assembly electrodes and the plurality of second assembly electrodes disposed in the curved portion can have different sizes from each other.

In the curved portion, when the size of each of the plurality of first assembly electrodes is smaller than the size of each of the plurality of second assembly electrodes, the plurality of light emitting diodes can be disposed to be tilted toward the plurality of first assembly electrodes.

In the curved portion, each of the plurality of pockets can be disposed to be biased toward the plurality of first assembly electrodes, between the plurality of first assembly electrodes and the plurality of second assembly electrodes.

The display device can further include a third insulating layer which covers any one of the plurality of first assembly electrodes and the plurality of second assembly electrodes disposed in the curved portion. In the curved portion, the plurality of light emitting diodes can be disposed to be tilted toward the assembly electrode which is disposed to be spaced apart from the third insulating layer, between the plurality of first assembly electrodes and the plurality of second assembly electrodes.

The display device can further include a reflective film disposed on a bottom surface of each of the plurality of light emitting diodes.

The display device can further include a reflection layer disposed on the plurality of light emitting diodes and the first insulating layer or between the substrate and the plurality of light emitting diodes.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate which defines a plurality of sub pixels and has a flat portion and a curved portion;
a plurality of first assembly electrodes disposed in each of the plurality of sub pixels;
a plurality of second assembly electrodes which is disposed in each of the plurality of sub pixels and is spaced apart from the plurality of first assembly electrodes;
a first insulating layer which is disposed on the plurality of first assembly electrodes and the plurality of second assembly electrodes and includes a plurality of pockets overlapping the plurality of sub pixels; and
a plurality of light emitting diodes disposed in the plurality of pockets of the first insulating layer,
wherein a width of a pocket located in the curved portion, among the plurality of pockets, is different from a width of another pocket located in the flat portion.

2. The display device according to claim 1, wherein the width of the pocket located in the curved portion is smaller than the width of the another pocket located in the flat portion.

3. The display device according to claim 1, wherein a slope of a light emitting diode disposed in the curved portion, among the plurality of light emitting diodes, is different from a slope of another light emitting diode disposed in the flat portion.

4. The display device according to claim 1, wherein the width of the pocket located in the curved portion varies according to an angle between a virtual plane extending from the flat portion and one surface of the substrate of the curved portion.

5. The display device according to claim 4, wherein the larger the angle between the virtual plane and one surface of the substrate of the curved portion, the smaller the width of the pocket located in the curved portion.

6. The display device according to claim 4, wherein the width of the pocket located in the curved portion is smaller than a maximum width of each of the plurality of light emitting diodes.

7. The display device according to claim 6, wherein the light emitting diode disposed in the curved portion, among the plurality of light emitting diodes, is disposed to be tilted toward any one of the first assembly electrode and the second assembly electrode.

8. The display device according to claim 4, wherein a width of the another pocket located in the flat portion is larger than a maximum width of each of the plurality of light emitting diodes.

9. The display device according to claim 8, wherein the another light emitting diode disposed in the flat portion, among the plurality of light emitting diodes, is disposed to be parallel to one surface of each of the first assembly electrode and the second assembly electrode.

10. The display device according to claim 1, wherein an emission layer of a light emitting diode disposed in the curved portion, among the plurality of light emitting diodes, is disposed to be tilted with respect to one surface of the substrate, and
wherein an emission layer of another light emitting diode disposed in the flat portion, among the plurality of light emitting diodes, is disposed to be parallel to the one surface of the substrate.

11. The display device according to claim 10, wherein the emission layer of the light emitting diode disposed in the curved portion and the emission layer of the another light emitting diode disposed in the flat portion are disposed to be parallel to each other.

12. The display device according to claim 10, wherein the emission layer of the light emitting diode disposed in the curved portion and the emission layer of the another light emitting diode disposed in the flat portion are disposed to be parallel to a virtual plane extending from the flat portion.

13. The display device according to claim 1, wherein the plurality of first assembly electrodes and the plurality of second assembly electrodes disposed in the flat portion have a same size, and
wherein the plurality of first assembly electrodes and the plurality of second assembly electrodes disposed in the curved portion have different sizes from each other.

14. The display device according to claim 13, wherein in the curved portion, when the size of each of the plurality of first assembly electrodes is smaller than the size of one of the plurality of second assembly electrodes, the plurality of light emitting diodes is disposed to be tilted toward the plurality of first assembly electrodes.

15. The display device according to claim 14, wherein in the curved portion, each of the plurality of pockets is disposed to be biased toward the plurality of first assembly electrodes, between the plurality of first assembly electrodes and the plurality of second assembly electrodes.

16. The display device according to claim 1, further comprising:
a third insulating layer which covers any one of the plurality of first assembly electrodes and the plurality of second assembly electrodes disposed in the curved portion,
wherein in the curved portion, the plurality of light emitting diodes is disposed to be tilted toward the assembly electrode which is disposed to be spaced apart from the third insulating layer, between the plurality of first assembly electrodes and the plurality of second assembly electrodes.

17. The display device according to claim 1, further comprising:
a reflective film disposed on a bottom surface of each of the plurality of light emitting diodes.

18. The display device according to claim 1, further comprising:
a reflection layer disposed on the plurality of light emitting diodes and the first insulating layer or between the substrate and the plurality of light emitting diodes.

19. The display device according to claim 1, wherein a light emission direction of one of the plurality of light emitting diodes in the flat portion is same as a light emission direction of another of the plurality of light emitting diodes in the curved portion, to implement a same level of front luminance for the display device.
